(19) United States
(12) Patent Application Publication
(10) Pub. No.: US 2026/0334039 A1
(43) Pub. Date: Oct. 22, 2026

(54) DISPLAY DEVICE, METHOD OF MANUFACTURING DISPLAY DEVICE, AND ELECTRONIC DEVICE INCLUDING DISPLAY DEVICE

(71) Applicant: Samsung Display Co., LTD., Yongin-si (KR)

(72) Inventors: EUNA YANG, Yongin-si (KR); HANSU KIM, Yongin-si (KR)

(21) Appl. No.: 19/463,855

(22) Filed: Jan. 29, 2026

(30) Foreign Application Priority Data
Jan. 31, 2025 (KR) 10-2025-0012375

(51) Int. Cl. H10K 59/38; H10K 59/12; H10K 59/80

(52) U.S. Cl. CPC H10K 59/38; H10K 59/1201; H10K 59/8792

(57) ABSTRACT

A display device includes a substrate, a plurality of light-emitting elements on the substrate, a thin-film encapsulation layer on the plurality of light-emitting elements, and a color filter layer on the thin-film encapsulation layer. The color filter layer includes color filters respectively overlapping the plurality of light-emitting elements. The color filters include convex color filters each having a convex top surface and flat color filters each having a flat top surface.

This application claims priority to Korean Patent Application No. 10-2025-0012375 filed on Jan. 31, 2025, and all the benefits accruing therefrom under 35 U.S.C. § 119, the content of which in its entirety is herein incorporated by reference.

### BACKGROUND

### 1. Field

One or more embodiments relate to a display device, a method of manufacturing the display device, and an electronic device including the display device.

### 2. Description of the Related Art

As various electronic devices, such as mobile phones, personal digital assistants (PDAs), computers, and large-screen televisions (TVs), have advanced, various types of display devices applicable thereto are under development. Examples of display devices widely used in the market include liquid crystal display devices including a backlight unit or organic light-emitting display devices in which pixels emit pieces of light of different colors.

The above information disclosed in this Background section is for enhancement of understanding of the background of the disclosure, and therefore, it may contain information that does not constitute related art.

### SUMMARY

One or more embodiments may provide a display device capable of controlling light efficiency, a viewing angle, and an external light reflection distribution, a method of manufacturing the display device, and an electronic device including the display device.

However, the technical problems to be solved by the disclosure are not limited to those described herein, and other problems that are not mentioned herein will be clearly understood from the following description by those of ordinary skill in the art.

According to one or more embodiments, a display device includes a substrate, a plurality of light-emitting elements on the substrate, a thin-film encapsulation layer on the plurality of light-emitting elements, and a color filter layer on the thin-film encapsulation layer, wherein the color filter layer includes color filters respectively overlapping the plurality of light-emitting elements, the color filters include convex color filters each having a convex top surface and flat color filters each having a flat top surface, and some of the convex color filters and some of the flat color filters respectively overlap light-emitting elements which emit light of a same color.

In an embodiment, the color filter layer may further include a black matrix surrounding the color filters, and the black matrix may include first openings in which the convex color filters are disposed and second openings in which the flat color filters are disposed.

In an embodiment, a first convex color filter of any one of the convex color filters and a first flat color filter of any one of the flat color filters may respectively overlap the light-emitting elements which emit the light of the same color.

In an embodiment, the first convex color filter and the first flat color filter may include a same pigment, and a concentration of the pigment as included in the first convex color filter may be lower than a concentration of the pigment as included in the first flat color filter.

In an embodiment, the display device may further include a monomer layer below the first convex color filter.

In an embodiment, the first convex color filter and the first flat color filter may include a same pigment, and a volume and a concentration of the pigment as included in the first convex color filter may be equal to a volume and a concentration of the pigment as included in the first flat color filter.

In an embodiment, a first thickness of the black matrix surrounding the convex color filters may be less than a second thickness of the black matrix surrounding the flat color filters.

In an embodiment, a top surface of the black matrix may be hydrophobic, and inner surfaces of the second openings may be hydrophilic.

In an embodiment, the display device may further include a hydrophilic layer on lower portions of the flat color filters and on the inner surfaces of the second openings.

In an embodiment, each of the plurality of light-emitting elements may include a pixel electrode, a common electrode on the pixel electrode, and a light-emitting layer between the pixel electrode and the common electrode, the display device may further include a pixel defining layer covering edges of the pixel electrode and defining emission areas of the plurality of light-emitting elements, and the color filters may be disposed to respectively correspond to the emission areas.

According to one or more embodiments, a method of manufacturing a display device includes forming a display layer including a substrate, a plurality of light-emitting elements, and a thin-film encapsulation layer, and forming a color filter layer on the display layer, wherein the color filter layer includes color filters formed by inkjet printing, and the color filters respectively overlap the plurality of light-emitting elements and include convex color filters each having a convex top surface and flat color filters each having a flat top surface.

In an embodiment, the forming of the color filter layer may include forming a black matrix including openings, injecting ink, which is a material for the color filters, into the openings, and irradiating the injected ink with light, and the openings may include first openings in which the convex color filters are disposed and second openings in which the flat color filters are disposed.

In an embodiment, the injecting of the ink may include injecting the ink into the second openings and then injecting the ink into the first openings.

In an embodiment, the method may further include, between the forming of the black matrix and the injecting of the ink, forming a monomer layer in the first openings.

In an embodiment, the method may further include, between the forming of the black matrix and the injecting of the ink, surface-treating a top surface of the black matrix such that the top surface is hydrophobic and surface-treating inner surfaces of the second openings such that the inner surfaces are hydrophilic.

In an embodiment, the surface-treating of the inner surfaces of the second openings such that the inner surfaces are hydrophilic may include forming a hydrophilic layer on lower portions of the flat color filters and the inner surfaces of the second openings.

In an embodiment, a first convex color filter of any one of the convex color filters and a first flat color filter of any one of the flat color filters may respectively overlap light-emitting elements which emit light of a same color.

In an embodiment, a depth of the first opening may be less than a depth of the second opening.

According to one or more embodiments, an electronic device including a display device includes a substrate, a plurality of light-emitting elements on the substrate, a thin-film encapsulation layer on the plurality of light-emitting elements, and a color filter layer on the thin-film encapsulation layer, wherein the color filter layer includes color filters respectively overlapping the plurality of light-emitting elements, and the color filters include convex color filters each having a convex top surface and flat color filters each having a flat top surface.

In an embodiment, a first convex color filter of any one of the convex color filters and a first flat color filter of any one of the flat color filters may respectively overlap light-emitting elements which emit light of a same color.

### BRIEF DESCRIPTION OF THE DRAWINGS

The above and other aspects, features, and advantages of certain embodiments of the disclosure will be more apparent from the following description taken in conjunction with the accompanying drawings in which:

FIG. 1 is a plan view schematically illustrating a portion of a display device according to an embodiment;

FIG. 2 is a cross-sectional view schematically illustrating an example of region I of the display device illustrated in FIG. 1;

FIG. 3 is a plan view schematically illustrating a portion of a display device according to an embodiment;

FIG. 4 is a cross-sectional view schematically illustrating an example of an I-I′ cross-section of FIG. 3;

FIGS. 5A and 5B are cross-sectional views illustrating an example of a process of manufacturing the display device of FIG. 4;

FIG. 6 is a cross-sectional view schematically illustrating another example of the I-I′ cross-section of FIG. 3;

FIG. 7 is a cross-sectional view schematically illustrating another example of the I-I′ cross-section of FIG. 3;

FIGS. 8A and 8B are cross-sectional views illustrating an example of a process of manufacturing a display device of FIG. 7;

FIG. 9 is a cross-sectional view schematically illustrating another example of the I-I′ cross-section of FIG. 3;

FIGS. 10A to 10C are cross-sectional views illustrating an example of a process of manufacturing a display device of FIG. 9;

FIG. 11 is a block diagram of an electronic device according to an embodiment; and

FIG. 12 is a schematic diagram of electronic devices according to various embodiments.

### DETAILED DESCRIPTION

As the present description allows for various changes and numerous embodiments, certain embodiments will be illustrated in the drawings and described in detail in the written description. Effects and features of the disclosure, and methods of achieving them will be clarified with reference to embodiments described herein in detail with reference to the drawings. However, the disclosure is not limited to the following embodiments and may be embodied in various forms.

In the following embodiments, the terms “first,” “second,” and the like are not used in a restrictive sense and are used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

In the following embodiments, it will be understood that, when a portion such as unit, region, or element is referred to as being “on” another portion, this may include not only a case where the portion is directly on the other portion, but also a case where intervening units, regions, or elements may be present therebetween.

In the following embodiments, it will be understood that the terms “connection” or “coupling” do not necessarily mean “direct and/or fixed connection or coupling” of two members, unless the context clearly indicates otherwise, and this does not preclude the disposition of other members between the two members.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel. The term “substantially flat” means approximately or actually flat.

In some aspects, sizes of elements in the drawings may be exaggerated or reduced for convenience of explanation. For example, because sizes and/or thicknesses of elements in the drawings are arbitrarily illustrated for convenience of explanation, the disclosure is not limited thereto.

Hereinafter, embodiments will be described in detail with reference to the accompanying drawings. When describing embodiments with reference to the accompanying drawings, the same or corresponding elements are denoted by the same reference numerals, and redundant descriptions thereof are omitted.

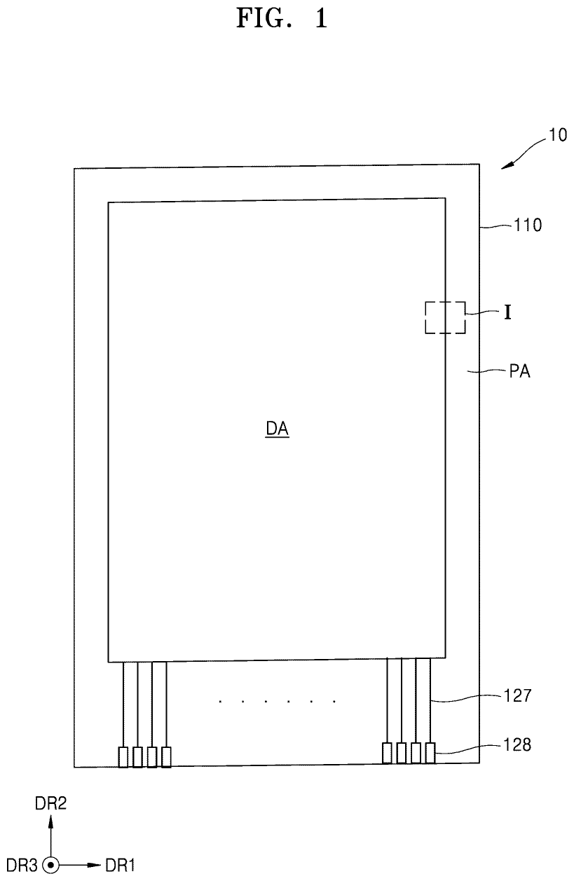

FIG. 1 is a plan view schematically illustrating a portion of a display device 10 according to an embodiment.

Referring to FIG. 1, the display device 10 may include a display area DA in which an image is displayed on a substrate 110 and a peripheral area PA which is a non-display area outside the display area DA and in which no image is displayed.

The display area DA may have a rectangular shape. The peripheral area PA may surround the display area DA. However, the disclosure is not limited thereto, and the shape of the display area DA and the shape of the peripheral area PA may be designed relatively.

The display area DA may include a plurality of light-emitting elements. A wiring portion 127 including signal lines (e.g., scan lines and data lines electrically connected to the plurality of light-emitting elements) and power lines (e.g., driving voltage lines) may be electrically connected to a pad electrode 128.

In an embodiment, the display device 10 having a flat display surface is illustrated, but the disclosure is not limited thereto. The display device 10 may include a curved display surface or a three-dimensional display surface. The three-dimensional display surface may include a plurality of display areas indicating different directions, and may include, for example, a polygonal columnar display surface.

The display device 10 according to the present embodiment may be a rigid display device. However, the disclosure is not limited thereto, and the display device 10 according to the disclosure may be a flexible display device. In an embodiment, the display device 10 applicable to a portable terminal is illustrated as an example. Although not illustrated, electronic modules, camera modules, power modules, or the like mounted on a main board may be accommodated in a housing to constitute the portable terminal. The display device 10 according to the disclosure may be applicable to large electronic devices, such as televisions (TVs) or monitors, and small and medium electronic devices, such as tablets, car navigation systems, game consoles, or smart watches.

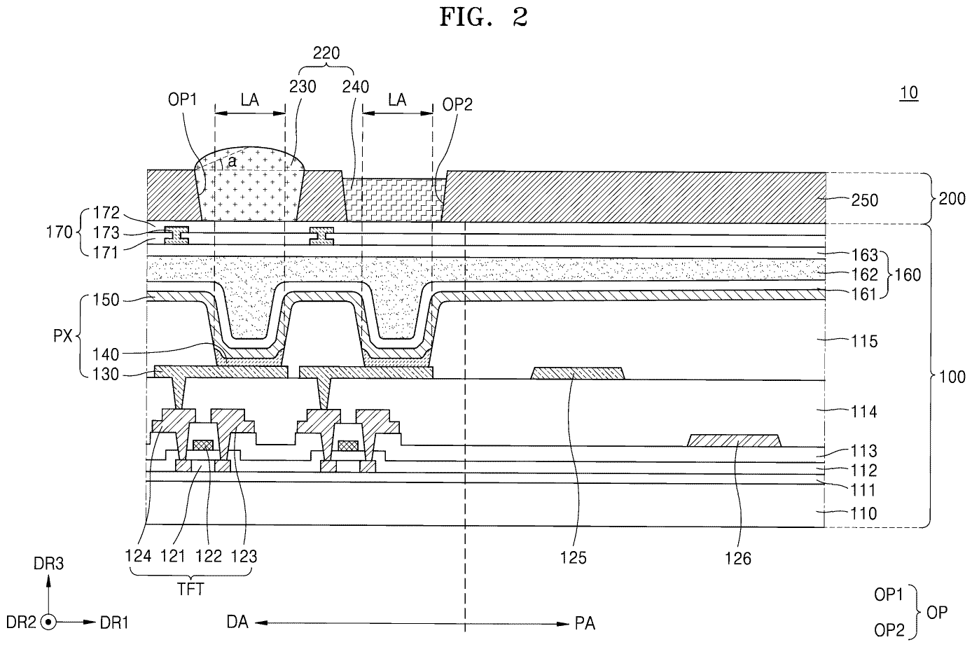

FIG. 2 is a cross-sectional view schematically illustrating an example of region I of the display device 10 illustrated in FIG. 1.

Referring to FIG. 2, the display device 10 may include a display layer 100 and a color filter layer 200 on the display layer 100. The display layer 100 may include a substrate 110, a thin-film transistor TFT on the substrate 110, a plurality of light-emitting elements PX electrically connected to the thin-film transistor TFT on the thin-film transistor TFT, and a thin-film encapsulation layer 160 on the plurality of light-emitting elements PX.

The display device 10 may include the color filter layer 200 disposed on the display layer 100, specifically the thin-film encapsulation layer 160. The color filter layer 200 may include color filters 220 respectively overlapping the light-emitting elements PX.

The display layer 100 may further include a passivation layer 114 between the thin-film transistor TFT and the light-emitting element PX, the thin-film encapsulation layer 160 on the light-emitting element PX, and a touch sensing layer 170 on the thin-film encapsulation layer 160.

The color filter layer 200 may include the color filters 220 on the touch sensing layer 170 and a black matrix 250 on the same plane as the color filters 220.

Although not illustrated, the display device 10 may further include other components on the color filter layer 200. As an example, a window substrate, a cover member, or the like may be further disposed on the color filter layer 200.

The substrate 110 may include various materials, such as glass, metal, or plastic. For example, the substrate 110 may be a flexible substrate including polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate.

The plurality of thin-film transistors TFT may be disposed on the substrate 110. The display area DA is an area in which an image is displayed, and the plurality of thin-film transistors TFT and the plurality of light-emitting elements PX electrically connected on the plurality of thin-film transistors TFT may be disposed in the display area DA.

A buffer layer 111 including an inorganic material, such as silicon oxide, silicon nitride, and/or silicon oxynitride, may be disposed between the thin-film transistor TFT and the substrate 110. The buffer layer 111 may increase the smoothness of the top surface of the substrate 110 or may prevent or reduce infiltration of impurities into a semiconductor layer 121 through the substrate 110.

The thin-film transistor TFT may include the semiconductor layer 121, a gate electrode 122, a source electrode 123, and a drain electrode 124.

The semiconductor layer 121 may include amorphous silicon, polycrystalline silicon, or an organic semiconductor material.

The gate electrode 122 may be disposed on the semiconductor layer 121. The source electrode 123 and the drain electrode 124 may be electrically connected to each other according to a signal applied to the gate electrode 122. The gate electrode 122 may include a single layer or layers including one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), taking into account adhesion to adjacent layers, surface flatness of the stacked layers, and processability.

To ensure electrical insulating properties between the semiconductor layer 121 and the gate electrode 122, a gate insulating layer 112 including an inorganic material, such as silicon oxide, silicon nitride, and/or silicon oxynitride, may be disposed between the semiconductor layer 121 and the gate electrode 122.

An interlayer insulating layer 113 including an inorganic material, such as silicon oxide, silicon nitride, and/or silicon oxynitride, may be disposed on the gate electrode 122.

The source electrode 123 and the drain electrode 124 may be disposed on the interlayer insulating layer 113. The source electrode 123 and the drain electrode 124 may each be electrically connected to the semiconductor layer 121 through contact holes formed in the interlayer insulating layer 113 and the gate insulating layer 112.

The source electrode 123 and the drain electrode 124 may each include a single layer or layers including one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

Various structures and wirings may be disposed in the peripheral area PA of the substrate 110. For example, a first power supply line 125 configured to apply low-voltage power to the light-emitting element PX and a second power supply line 126 configured to apply high-voltage power to the light-emitting element PX are illustrated in FIG. 2.

The passivation layer 114, which acts as a planarization layer, may be disposed on the thin-film transistor TFT. The passivation layer 114 may include an organic insulating material or an inorganic insulating material, or may include a composite of an organic insulating material and an inorganic insulating material. The passivation layer 114 may include an organic material, such as acryl, benzocyclobutene (BCB), polyimide, or hexamethyldisiloxane (HMDSO).

In the display area DA, the light-emitting element PX electrically connected to the thin-film transistor TFT may be disposed on the passivation layer 114.

The light-emitting element PX may include a pixel electrode 130, a common electrode 150 on the pixel electrode 130, and an emission layer 140 between the pixel electrode 130 and the common electrode 150.

The pixel electrode 130 may be disposed on the passivation layer 114. The pixel electrode 130 may be connected to the drain electrode 124 of the thin-film transistor TFT through a via hole formed in the passivation layer 114.

The pixel electrode 130 may be conductive. The pixel electrode 130 may include a metal alloy or a conductive compound. The pixel electrode 130 may be an anode.

The pixel electrode 130 may be a transmissive electrode, a transflective electrode, or a reflective electrode. In an example in which the pixel electrode 130 is a transmissive electrode, the pixel electrode 130 may include a transparent metal oxide, for example, indium tin oxide (ITO), indium zinc oxide (IZO), zinc oxide (ZnO), indium tin zinc oxide (ITZO), or the like.

In an example in which the pixel electrode 130 is a transflective electrode or a reflective electrode, the pixel electrode 130 may include Ag, Mg, Cu, Al, Pt, Pd, Au, Ni, Nd, Ir, Cr, Li, Ca, LiF/Ca, LiF/Al, Mo, Ti, or any compound or mixture thereof (e.g., a mixture of Ag and Mg). For example, the pixel electrode 130 may have a multilayer structure including a reflective layer or a transflective layer including the material described herein and a transparent conductive layer including ITO, IZO, ZnO, ITZO, or the like. For example, the pixel electrode 130 may have a three-layer structure of ITO/Ag/ITO, but the disclosure is not limited thereto.

The emission layer 140 may have a multilayer structure including a single layer including a single material, a single layer including a plurality of different materials, or a plurality of layers including a plurality of different materials.

An intermediate layer (not illustrated) including the emission layer 140 may be disposed on the pixel electrode 130.

The intermediate layer may include a low molecular weight material or a high molecular weight material. In an example in which the intermediate layer includes a low molecular weight material, the intermediate layer may have a structure in which a hole injection layer, a hole transport layer, an electron transport layer, and an electron injection layer are stacked alone or in combination. The intermediate layer may include various organic materials including copper phthalocyanine, N, N′-di(naphthalene-1-yl)-N,N′-diphenyl-benzidine (NPB), tris-8-hydroxyquinoline aluminum (Alq3), or the like. The intermediate layer may be formed by various methods, for example, vacuum deposition.

In an example in which the intermediate layer includes a high molecular weight material, the intermediate layer may usually include a hole transport layer. In this case, the hole transport layer may include poly(3,4-ethylenedioxythiophene (PEDOT) and the emission layer may include a polymer material, such as poly-phenylenevinylene (PPV) or polyfluorene. The intermediate layer may be formed by various methods, for example, screen printing, inkjet printing, or laser induced thermal imaging (LITI).

The intermediate layer may be a layer formed integrally across a plurality of pixel electrodes 130, or may be a layer patterned to correspond to each of the plurality of pixel electrodes 130.

The common electrode 150 formed integrally across all the light-emitting elements PX may be disposed on the emission layers 140 of the light-emitting elements PX.

The common electrode 150 may be a transmissive electrode, a transflective electrode, or a reflective electrode. In an example in which the common electrode 150 is a transmissive electrode, the common electrode 150 may include a transparent metal oxide, for example, ITO, IZO, ZnO, ITZO, or the like.

The common electrode 150 may be a transmissive electrode. In an example in which the common electrode 150 is a transmissive electrode, the common electrode may include one or more materials selected from Ag, Al, Mg, Li, Ca, Cu, LiF/Ca, LiF/Al, MgAg, and CaAg, and may be formed as a thin-film having a thickness of several to tens of nanometers (nm).

The light-emitting element PX may include a first light-emitting element, a second light-emitting element, and a third light-emitting element, which are spaced apart from each other. As an example, the first light-emitting element may be configured to emit red light, the second light-emitting element may be configured to emit green light, and the third light-emitting element may be configured to emit blue light.

A pixel defining layer 115 may be disposed between the pixel electrodes 130 of the light-emitting elements PX and the common electrode 150.

The pixel defining layer 115 may include a groove surrounding edges of the pixel electrode 130 and exposing the central portion of the pixel electrode 130. In other words, the pixel defining layer 115 may cover the edges of the pixel electrode 130 and define an emission area LA of the light-emitting element PX.

The pixel defining layer 115 may include an organic material, such as polyimide or HMDSO. In an embodiment, the pixel defining layer 115 may include circular grooves each surrounding the periphery of the pixel electrode 130 and defining the emission area LA and may include a light-blocking material. The light-blocking material may include, for example, at least one of carbon black, carbon nanotubes (CNTs), or black dye.

The thin-film encapsulation layer 160 covering the display area DA may be disposed on the common electrode 150. The thin-film encapsulation layer 160 may seal the light-emitting element PX so as to prevent deterioration of the light-emitting element PX due to moisture and oxygen included in ambient air. The thin-film encapsulation layer 160 may include a first inorganic layer 161, an organic layer 162, and a second inorganic layer 163, as illustrated in FIG. 2.

The first inorganic layer 161 may include silicon oxide, silicon nitride, and/or silicon oxynitride.

The organic layer 162 may cover the first inorganic layer 161 which is uneven, and the top surface of the organic layer 162 may be substantially flat. The organic layer 162 may include at least one material selected from polyethylene terephthalate, polyethylene naphthalate, polycarbonate, polyimide, polyethylene sulfonate, polyoxymethylene, polyarylate, polyacrylate, and HMDSO.

The second inorganic layer 163 may cover the organic layer 162 and may include silicon oxide, silicon nitride, and/or silicon oxynitride.

The thin-film encapsulation layer 160 has a multilayer structure including the first inorganic layer 161, the organic layer 162, and the second inorganic layer 163. Thus, in an example in which cracks occur in the thin-film encapsulation layer 160, the multilayer structure of the thin-film encapsulation layer 160 may prevent the cracks from connecting to each other between the first inorganic layer 161 and the organic layer 162 or between the organic layer 162 and the second inorganic layer 163. This may prevent or reduce the formation of a path through which ambient moisture or oxygen penetrates into the display area DA.

Although not illustrated in FIG. 2, a capping layer (not illustrated), which improves light efficiency and protects the light-emitting element PX, may be further provided between the common electrode 150 and the thin-film encapsulation layer 160.

The touch sensing layer 170 may be disposed on the thin-film encapsulation layer 160. The touch sensing layer 170 may include a first insulating layer 171, a second insulating layer 172 on the first insulating layer 171, and a plurality of touch electrodes 173 between the first insulating layer 171 and the second insulating layer 172. The touch electrode 173 is not limited to the structure illustrated in FIG. 2, and may include various electrode structures, for example, a mesh electrode pattern or a transparent segment electrode.

The touch sensing layer 170 may be configured to sense touch input, based on a change in mutual capacitance caused by the touch input. In an example in which the touch input is applied, the mutual capacitance changes due to the touch input and a touch sensor (not illustrated) connected to the touch sensing layer 170 detects a changed position of the mutual capacitance. In this manner, the touch input may be sensed. However, the present embodiment is not limited to a particular touch sensing method.

The color filter layer 200 may be disposed on the display layer 100. For example, the color filters 220 may be disposed on the touch sensing layer 170, and the black matrix 250 may be disposed in the same plane as the color filters 220.

The color filters 220 may be disposed on the touch sensing layer 170 and may be disposed to respectively correspond to the emission areas LA of the light-emitting elements PX. In other words, the color filters 220 may respectively overlap the emission areas LA of the light-emitting elements PX.

The color filters 220 may be configured to filter light generated by the light-emitting element PX and transmit the filtered light to the outside. For example, a pigment included in the color filter 220 may block or transmit light of a specific wavelength.

By applying the color filters 220 instead of a polarizing layer to the display device 10, light output efficiency may be improved, the thickness of the display device 10 may be reduced, and stress during folding may be reduced.

The color filters 220 may be manufactured through a photo process or an inkjet process. The color filters 220 manufactured by the photo process has a uniform shape with a flat top surface, and thus, the color filters 220 may be vulnerable to lateral visibility and external light reflection.

Even for cases in which the color filters 220 are manufactured by the inkjet process, the display device 10 in which only the color filters 220 each having a convex top surface are formed may have reduced front light efficiency, and the display device 10 in which only the color filters 220 each having a flat top surface are formed may have reduced lateral visibility and may be vulnerable to external light reflection.

The color filters 220 each having a flat top surface has good front light efficiency, but may have a disadvantage in that visibility is reduced because the reflection of external light is induced only in a specific direction. The color filters 220 each having a convex top surface may have an advantage in that external light is dispersed and lateral visibility is improved, but may have a disadvantage in that front light efficiency is reduced.

To appropriately combine the advantage of the color filters 220 each having a convex top surface and flat color filters 240 each having a flat top surface, the color filters 220 of the display device 10 may include convex color filters 230 each having a convex top surface and flat color filters 240 each having a flat top surface. The convex color filters 230 and the flat color filters 240 may be appropriately disposed to control lateral visibility, external light reflection dispersion, and light efficiency.

In an example in which an angle between a plane connecting points where the black matrix 250 meets the top surface of the color filter 220 and a line connecting a point where the black matrix 250 meets the color filter 220 to the uppermost end of the color filter 220 is defined as a taper angle a, the color filter 220 having a taper angle a of 25° or more may be referred to as the convex color filter 230, and the color filter 220 having a taper angle a of 25° or less may be referred to as the flat color filter 240. The taper angle a of the convex color filter 230 may be, for example, 30° or more, and the taper angle a of the flat color filter 240 may be, for example, 20° or less.

The color filter layer 200 may include the black matrix 250. The black matrix 250 may be disposed to surround the color filter 220 on the touch sensing layer 170.

The black matrix 250 may be disposed on the pixel defining layer 115 and may define an opening area through which light passes. In other words, the black matrix 250 may include an opening corresponding to the groove of the pixel defining layer 115 defining the emission area LA. The color filter 220 may be disposed in the opening.

The black matrix 250 of the display area DA may have the opening which opens the emission area LA of the light-emitting element PX. The opening of the black matrix 250 may be disposed to overlap the groove formed in the pixel defining layer 115.

The opening may include a first opening OP1 including the convex color filter 230 and a second opening OP2 including the flat color filter 240.

The surface of the black matrix 250 may be hydrophobic. Due to this, the color filter 220 may not overflow into the black matrix 250. Because at least the top surface of the black matrix 250 is hydrophobic, the top surface of the convex color filter 230 can become more convex.

The inner surface of the opening may be hydrophilic. Due to this, the color filter 220 may be well contained in the opening. In particular, the top surface of the flat color filter 240 may be flat because the inner surface of the second opening OP2 is hydrophilic.

The black matrix 250 of the peripheral area PA may surround the entire peripheral area PA without an opening. The black matrix 250 surrounding the peripheral area PA may reduce external light reflection by various wirings disposed in the peripheral area PA.

The black matrix 250 may include a light-blocking material. As an example, the black matrix 250 may include at least one of a metal or opaque organic layer material, such as chromium oxide (CrOₓ), carbon black, CNTs, or a black dye. The black matrix 250 may include a coloring agent, such as a pigment or a dye. The black matrix 250 may have a single-layer or multilayer structure.

Unlike that illustrated in FIG. 2, the black matrix 250 may cover some color filters 220 and the color filters 220 may cover a portion of the black matrix 250, depending on the formation order of the black matrix 250 and the color filters 220.

In other embodiments, the color filter layer 200 may have the same effect as the black matrix 250 by using a combination of a first color filter, a second color filter, and a third color filter, instead of the black matrix 250.

The display device 10 in which visibility and light efficiency are adjusted by appropriately disposing the convex color filter 230 having a convex top surface and the flat color filter 240 having a flat top surface is described herein.

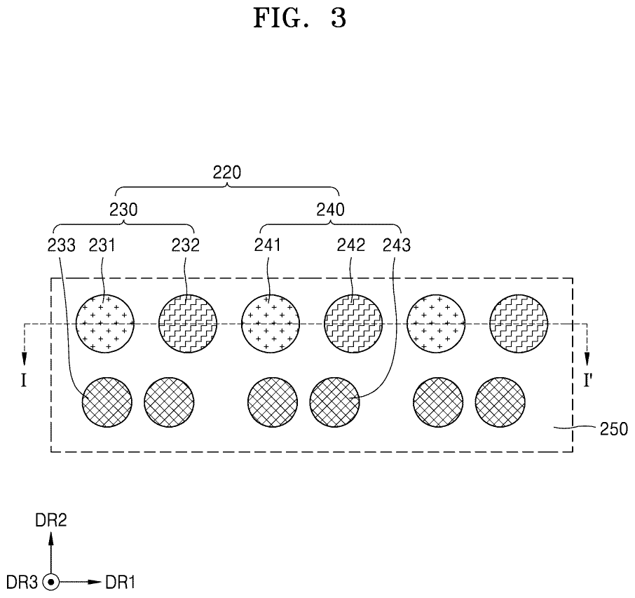

FIG. 3 is a plan view schematically illustrating a portion of a display device according to an embodiment. Specifically, FIG. 3 is a plan view of the display device, when viewed from above color filters 220 and a black matrix 250 of a display area DA.

Referring to FIG. 3, convex color filters 230 and flat color filters 240 may be alternately disposed in the same row. Although not illustrated, the convex color filters 230 and the flat color filters 240 may be alternately disposed in the same column.

However, the expression “alternately disposed” is not limited to meaning that one flat color filter 240 is disposed after one convex color filter 230. In the present specification, the expression “alternately disposed” may mean that one convex color filter 230 and one flat color filter 240 are alternately disposed, may mean that a plurality of convex color filters 230 and a plurality of flat color filters 240 are alternately disposed, may mean that one convex color filter 230 and a plurality of flat color filters 240 are alternately disposed, or may mean that a plurality of convex color filters 230 and one flat color filter 240 are alternately disposed.

The convex color filters 230 may each include a first convex color filter 231 and a second convex color filter 232. The flat color filters 240 may each include a first flat color filter 241 and a second flat color filter 242. In some embodiments, the convex color filters 230 may each further include a third convex color filter 233, and the flat color filters 240 may each further include a third flat color filter 243.

The first convex color filter 231 and the second convex color filter 232, and the first flat color filter 241 and the second flat color filter 242 may be alternately disposed in the same first row. The third convex color filter 233 and the third flat color filter 243 may be disposed in a second row which is different from the first row in which the first convex color filter 231, the second convex color filter 232, the first flat color filter 241, and the second flat color filter 242 are disposed.

The first row and the second row may be alternately disposed along a second direction DR2. The first convex color filter 231, the second convex color filter 232, the first flat color filter 241, and the second flat color filter 242 may be alternately disposed in the first rows which are most adjacent to each other along the second direction DR2.

As another example, the first convex color filter 231, the second convex color filter 232, the third convex color filter 233, the first flat color filter 241, the second flat color filter 242, and the third flat color filter 243 may be sequentially disposed in the same row. In some embodiments, the first convex color filter 231, the second convex color filter 232, the third convex color filter 233, the first flat color filter 241, the second flat color filter 242, and the third flat color filter 243 may be sequentially disposed in the same column.

The first convex color filter 231, the second convex color filter 232, the third convex color filter 233, the first flat color filter 241, the second flat color filter 242, and the third flat color filter 243 may be disposed in a distributed manner in accordance with a certain rule, instead of being densely disposed in the display area DA. The disclosure is not limited to the form illustrated in FIG. 3, and the color filters 220 may be disposed in various forms.

In an embodiment, the first convex color filter 231, the second convex color filter 232, the third convex color filter 233, the first flat color filter 241, the second flat color filter 242, and the third flat color filter 243, which have different planar areas, are illustrated as an example, but the disclosure is not limited thereto. Among the color filters 220, the first convex color filter 231, the second convex color filter 232, the first flat color filter 241, and the second flat color filter 242 are illustrated as having large areas, and the third convex color filter 233 and the third flat color filter 243 are illustrated as having small areas, but this is an example.

As an example, the total areas of the first convex color filters 231, the second convex color filters 232, the third convex color filters 233, the first flat color filters 241, the second flat color filters 242, and the third flat color filters 243 may be equal to each other. As another example, in an example in which the first convex color filter 231, the second convex color filter 232, the third convex color filter 233, the first flat color filter 241, the second flat color filter 242, and the third flat color filter 243 all have the same area, the first convex color filter 231, the second convex color filter 232, the third convex color filter 233, the first flat color filter 241, the second flat color filter 242, and the third flat color filter 243 may be disposed in the display area DA in the same number.

Some convex color filters 230 and some flat color filters 240 may respectively overlap light-emitting elements PX which emit light of the same color.

For example, the first convex color filter 231 of any one of the convex color filters 230 and the first flat color filter 241 of any one of the flat color filters 240 may respectively overlap light-emitting elements PX which emit light of the same color.

The color filters 220 may include the first convex color filter 231 and the first flat color filter 241 disposed on the first light-emitting element, the second convex color filter 232 and the second flat color filter 242 disposed on the second light-emitting element, and the third convex color filter 233 and the third flat color filter 243 disposed on the third light-emitting element.

The color filters 220 may include a plurality of colors respectively corresponding to the emission areas LA of the light-emitting elements PX. For example, in an example in which the first light-emitting element emits red light, the first convex color filter 231 and the first flat color filter 241 may filter the red light, in an example in which the second light-emitting element emits green light, the second convex color filter 232 and the second flat color filter 242 may filter the green light, and in an example in which the third light-emitting element emits blue light, the third convex color filter 233 and the third flat color filter 243 may filter the blue light.

In this case, the first convex color filter 231 and the first flat color filter 241, which are red color filters, may include a red pigment or dye, the second convex color filter 232 and the second flat color filter 242, which are green color filters, may include a green pigment or dye, and the third convex color filter 233 and the third flat color filter 243, which are blue color filters, may include a blue pigment or dye. The red pigment, the green pigment, and the blue pigment may be any known pigment commonly used to form color filters. For example, a pigment of a C.I. pigment red series may be used as the red pigment, a pigment of a C.I. pigment green series may be used as the green pigment, and a phthalocyanine-based pigment or an indanthrone blue pigment may be used as the blue pigment.

In an embodiment, the plurality of color filters 220 each having a circular shape are illustrated, but the shape of the color filters 220 is not limited thereto, and the color filters 220 may each have a polygonal shape.

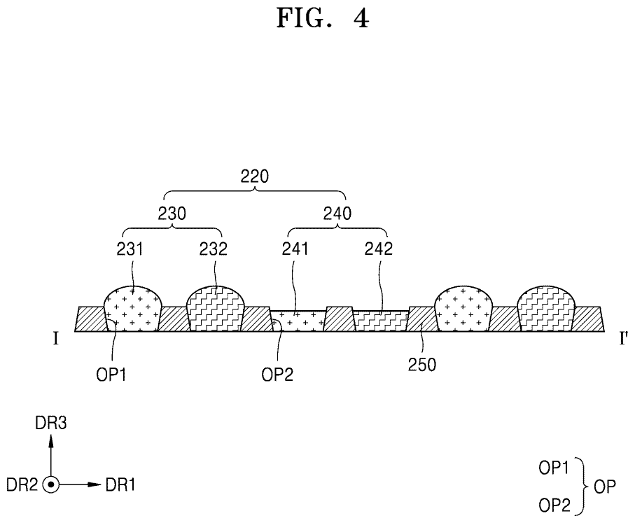

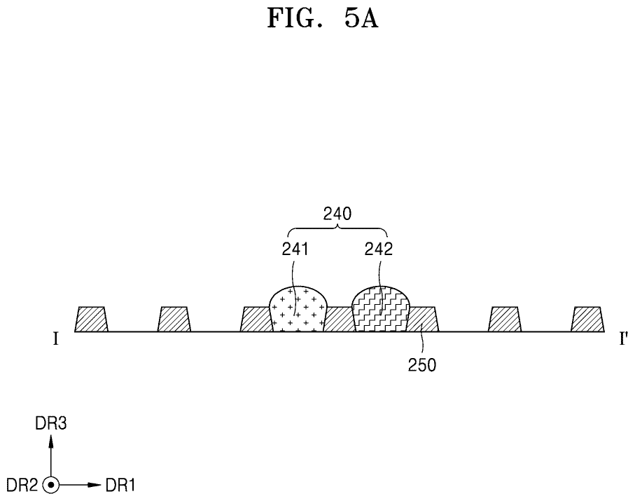

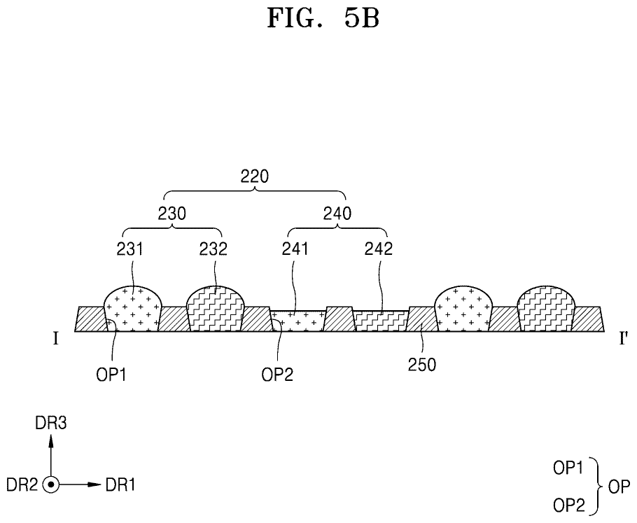

FIG. 4 is a cross-sectional view schematically illustrating an example of an I-I′ cross-section of FIG. 3, and FIGS. 5A and 5B are cross-sectional views illustrating an example of a process of manufacturing the display device of FIG. 4.

Referring to FIG. 4, the color filters 220 may include the convex color filters 230 each having a convex top surface and the flat color filters 240 each having a flat top surface.

The convex color filters 230 and the flat color filters 240 may be alternately disposed in a repetitive pattern.

The proportion of the convex color filters 230 may be increased so as to improve lateral visibility and external light reflection, and the proportion of the flat color filters 240 may be increased so as to improve front light efficiency.

In other words, for the display device 10 with improved lateral visibility and improved external light reflection, the convex color filters 230 and the flat color filters 240 may be alternately disposed and the total area of the convex color filters 230 may be designed to be greater than the total area of the flat color filters 240. For the display device with improved front light efficiency, the convex color filters 230 and the flat color filters 240 may be alternately disposed and the total area of the flat color filters 240 may be designed to be greater than the total area of the convex color filters 230.

The color filter layer 200 may further include a black matrix 250 surrounding the color filters 220. The black matrix 250 may be disposed on the same plane as the color filters 220.

The black matrix 250 may include openings in which the color filters 220 are disposed. In other words, one color filter 220 may be disposed in one opening.

The openings may include first openings OP1 in which the convex color filters 230 are disposed and second openings OP2 in which the flat color filters 240 are disposed.

Each of the color filters 220 may include a specific pigment according to the light-emitting element PX below the corresponding color filter 220. The first convex color filter 231 and the first flat color filter 241 may include the same pigment. The concentration of the pigment in the first convex color filter 231 may be lower than the concentration of the pigment in the first flat color filter 241.

In an example in which the volume inside the first opening OP1 is equal to the volume inside the second opening OP2, the concentration of the pigment in the first convex color filter 231 may be lower than the concentration of the pigment in the first flat color filter 241. In an example in which the same pigment is included in the first convex color filter 231 and the first flat color filter 241, the volume of one first convex color filter 231 may be greater than the volume of one first flat color filter 241.

The descriptions of the volume and the concentration of the pigment in the first convex color filter 231 and the first flat color filter 241 may be equally applied between the second convex color filter 232 and the second flat color filter 242 and between the third convex color filter 233 and the third flat color filter 243.

The display device may be manufactured by changing the concentrations of the pigments in the convex color filter 230 and the flat color filter 240, and the convex color filter 230 and the flat color filter 240 may be manufactured at different times, as illustrated in FIGS. 5A and 5B.

Referring to FIGS. 5A and 5B, a method of manufacturing the display device, according to the disclosure, may include forming a display layer including a substrate, a plurality of light-emitting elements, and a thin-film encapsulation layer, and forming a color filter layer on the display layer. The color filter layer may include color filters 220 formed by inkjet printing.

The forming of the display layer may include preparing the substrate, forming the plurality of light-emitting elements on the substrate, and forming the thin-film encapsulation layer on the light-emitting elements.

The forming of the color filter layer may include forming a black matrix 250 including openings, injecting ink, which is a material for the color filters 220, into the openings, and irradiating the injected ink with light.

In the forming of the black matrix 250, the openings in which the color filters 220 are to be disposed may be formed. For example, first openings OP1 in which the convex color filters 230 are disposed and second openings OP2 in which the flat color filters 240 are disposed may be formed.

After the black matrix 250 is formed on the display layer, the method may include respectively forming the color filters 220 in the openings. The color filters 220 may be manufactured by inkjet printing.

The injecting of the ink may include injecting the ink into the second opening OP2 and then injecting the ink into the first opening OP1. The ink which is the material for the color filters 220 may be volatile. Due to this, the method may include injecting the ink into the first opening OP1 after the ink first injected into the second opening OP2 has evaporated to some extent (i.e., evaporated by a predetermined amount).

The flatness of the flat color filter 240 in the second opening OP2 may be controlled by adjusting the amount of time for the ink in the second opening OP2 to evaporate after the ink is injected into the second opening OP2 and before the ink is injected into the first opening OP1.

In an example, the method may include, after the ink is injected into the openings, irradiating the injected ink with light. In an example in which the ink is irradiated with the light, the ink hardens and becomes stable without flowing down. In other words, the ink irradiated with the light may form the color filters 220.

The color filters 220 manufactured by the method described herein may respectively overlap the light-emitting elements and include the convex color filters 230 each having a convex top surface and the flat color filters 240 each having a flat top surface. For example, the convex color filters 230 may be disposed in the first openings OP1, and the flat color filters 240 may be disposed in the second openings OP2.

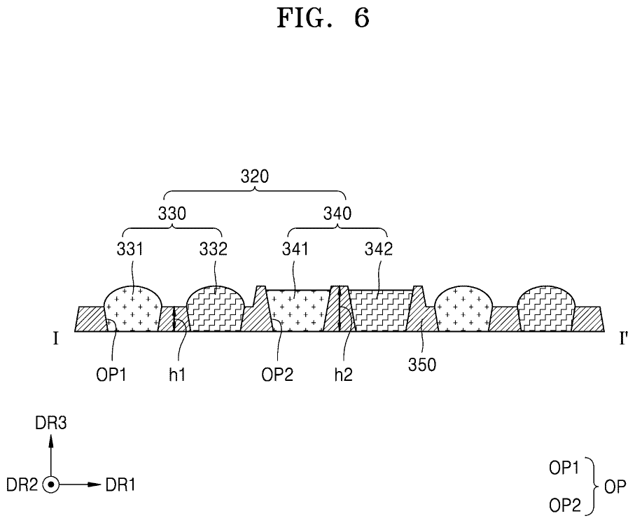

FIG. 6 is a cross-sectional view schematically illustrating another example of the I-I′ cross-section of FIG. 3.

Referring to FIG. 6, color filters 320 may include convex color filters 330 each having a convex top surface and flat color filters 340 each having a flat top surface.

The convex color filters 330 and the flat color filters 340 may be alternately disposed in a repetitive pattern.

The proportion of the convex color filters 330 may be increased so as to improve lateral visibility and external light reflection, and the proportion of the flat color filters 340 may be increased so as to improve front light efficiency.

In other words, for the display device with improved lateral visibility and improved external light reflection, the convex color filters 330 and the flat color filters 340 may be alternately disposed and the total area of the convex color filters 330 may be designed to be greater than the total area of the flat color filters 340. For the display device with improved front light efficiency, the convex color filters 330 and the flat color filters 340 may be alternately disposed and the total area of the flat color filters 340 may be designed to be greater than the total area of the convex color filters 330.

A color filter layer may include a black matrix 350 surrounding the color filters 320. The black matrix 350 may be disposed on the same plane as the color filters 320.

The black matrix 350 may include openings in which the color filters 320 are disposed. In other words, one color filter 320 may be disposed in one opening.

The openings may include first openings OP1 in which the convex color filters 330 are disposed and second openings OP2 in which the flat color filters 340 are disposed.

A first thickness h1 of the black matrix 350 surrounding the convex color filters 330 may be less than a second thickness h2 of the black matrix 350 surrounding the flat color filters 340. In other words, a depth of the first opening OP1 may be less than a depth of the second opening OP2.

Because the first thickness h1 is less than the second thickness h2, the concentration of the pigment in the convex color filters 330 may be equal to the concentration of the pigment in the flat color filters 340. The volume of one convex color filter 330 may be equal to the volume of one flat color filter 340. The volume inside the first opening OP1 may be equal to the volume inside the second opening OP2.

The color filters 320 may each include a specific pigment according to the light-emitting element below the corresponding color filter 320. At least a first convex color filter 331 and a first flat color filter 341 may include the same pigment. In some embodiments, the volume and the concentration of the pigment in the first convex color filter 331 may be equal to the volume and the concentration of the pigment in the first flat color filter 341.

The descriptions of the volume and the concentration of the pigment in the first convex color filter 331 and the first flat color filter 341 may be equally applied between a second convex color filter 332 and a second flat color filter 342 and between a third convex color filter and a third flat color filter.

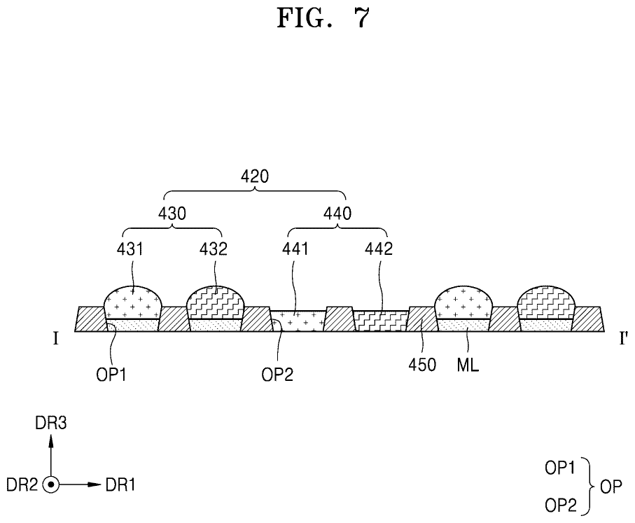

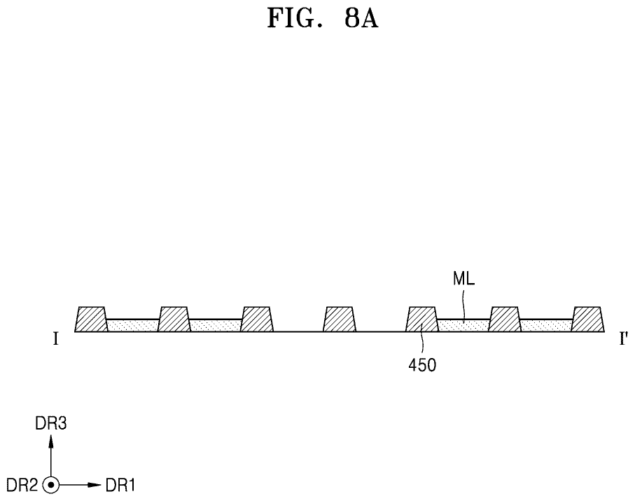

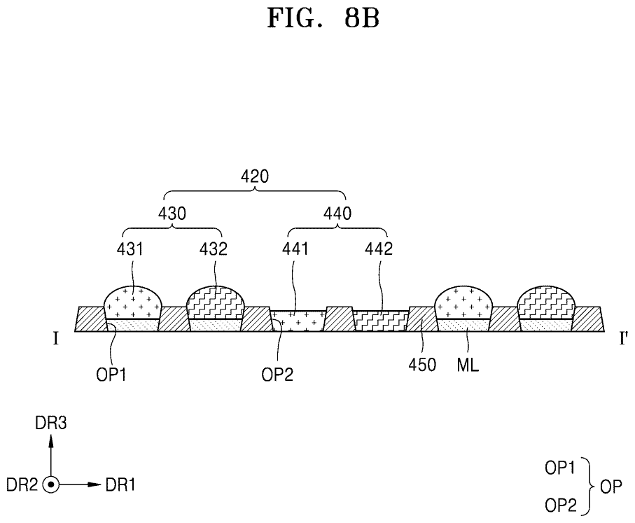

FIG. 7 is a cross-sectional view schematically illustrating another example of the I-I′ cross-section of FIG. 3, and FIGS. 8A and 8B are cross-sectional views illustrating an example of a process of manufacturing a display device of FIG. 7.

Referring to FIG. 7, color filters 420 may include convex color filters 430 each having a convex top surface and flat color filters 440 each having a flat top surface.

The convex color filters 430 and the flat color filters 440 may be alternately disposed in a repetitive pattern.

The proportion of the convex color filters 430 may be increased so as to improve lateral visibility and external light reflection, and the proportion of the flat color filters 440 may be increased so as to improve front light efficiency.

In other words, for the display device with improved lateral visibility and improved external light reflection, the convex color filters 430 and the flat color filters 440 may be alternately disposed and the total area of the convex color filters 430 may be designed to be greater than the total area of the flat color filters 440. For the display device with improved front light efficiency, the convex color filters 430 and the flat color filters 440 may be alternately disposed and the total area of the flat color filters 440 may be designed to be greater than the total area of the convex color filters 430.

A color filter layer may include a black matrix 450 surrounding the color filters 420. The black matrix 450 may be disposed on the same plane as the color filters 420.

The black matrix 450 may include openings in which the color filters 420 are disposed. In other words, one color filter 420 may be disposed in one opening.

The openings may include first openings OP1 in which the convex color filters 430 are disposed and second openings OP2 in which the flat color filters 440 are disposed.

The color filters 420 may each include a specific pigment according to the light-emitting element PX below the corresponding color filter 420. A first convex color filter 431 and a first flat color filter 441 may include the same pigment.

The display device may further include a monomer layer ML below the convex color filter 430. The monomer layer ML may be disposed below at least the first convex color filter 431.

As the monomer layer ML is disposed, the volume and the concentration of the pigment in the convex color filter 430 may be equal to the volume and the concentration of the pigment in the flat color filter 440. For example, the volume and the concentration of the pigment in the first convex color filter 431 may be equal to the volume and the concentration of the pigment in the first flat color filter 441.

The descriptions of the volume and the concentration of the pigment in the first convex color filter 431 and the first flat color filter 441 may be equally applied between a second convex color filter 432 and a second flat color filter 442 and between a third convex color filter and a third flat color filter.

Referring to FIGS. 8A and 8B, a method of manufacturing the display device, according to the disclosure, may include forming a display layer including a substrate, a plurality of light-emitting elements, and a thin-film encapsulation layer, and forming a color filter layer on the display layer. The color filter layer may include color filters 420 formed by inkjet printing.

The forming of the display layer may include preparing the substrate, forming the plurality of light-emitting elements on the substrate, and forming the thin-film encapsulation layer on the light-emitting elements.

The forming of the color filter layer may include forming a black matrix 450 including openings, injecting ink, which is a material for the color filters 420, into the openings, and irradiating the injected ink with light.

In the forming of the black matrix 450, the openings in which the color filters 420 are to be disposed may be formed. For example, first openings OP1 in which the convex color filters 430 are disposed and second openings OP2 in which the flat color filters 440 are disposed may be formed.

The method may further include, between the forming of the black matrix 450 and the injecting of the ink, forming a monomer layer ML in the first opening OP1.

After the black matrix 450 is formed on the display layer and the monomer layer ML is formed in the first opening OP1, color filters 420 may be formed in the openings. The color filters 420 may be manufactured by inkjet printing.

The monomer layer ML may be formed such that the ink may be simultaneously injected into the first openings OP1 and the second openings OP2. Because the monomer layer ML is disposed at a lower portion and the black matrix 450 has the same height, the ink may be convexly injected onto the monomer layer ML and flatly injected into the second openings OP2. Because the same volume of ink is simultaneously injected into the first openings OP1 and the second openings OP2, the process may be simplified and the process cost and process time may be reduced.

After the ink is injected into the openings, the ink may be manufactured into the color filters 420 by irradiating the ink with light.

As in the present manufacturing method, the convexity of the convex color filter 430 may be controlled by adjusting the thickness of the monomer layer ML.

The color filters 420 manufactured by the method described herein may respectively overlap the light-emitting elements and include the convex color filters 430 each having a convex top surface and the flat color filters 440 each having a flat top surface. For example, the convex color filters 430 may be disposed in the first openings OP1, and the flat color filters 440 may be disposed in the second openings OP2.

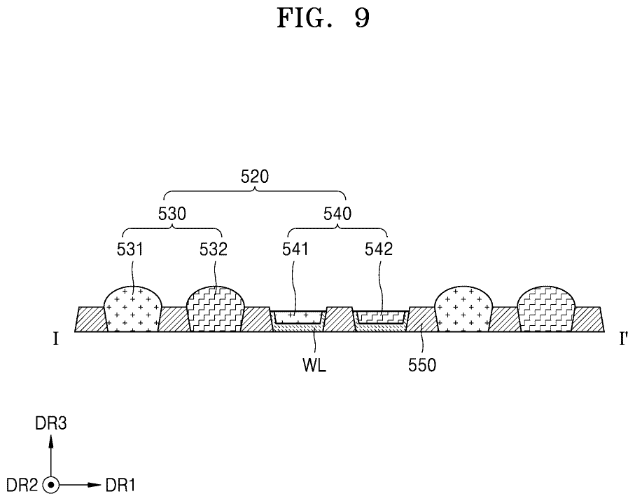

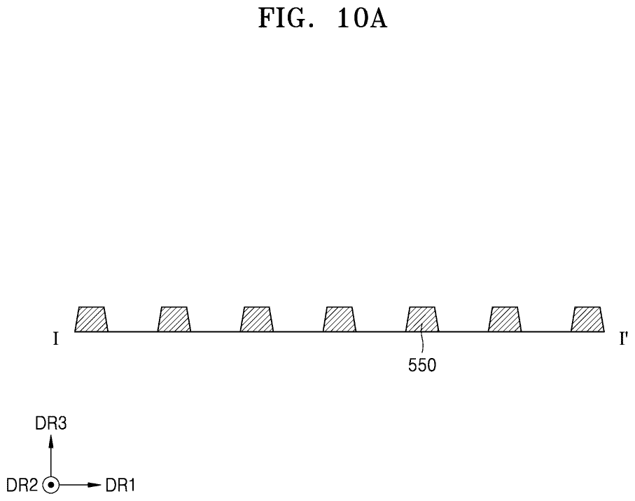

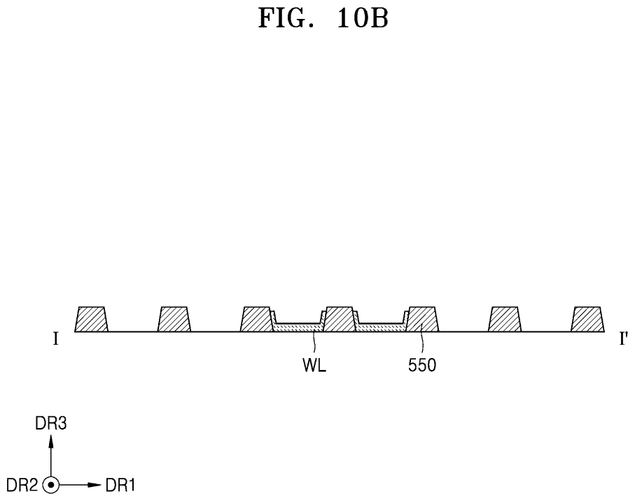

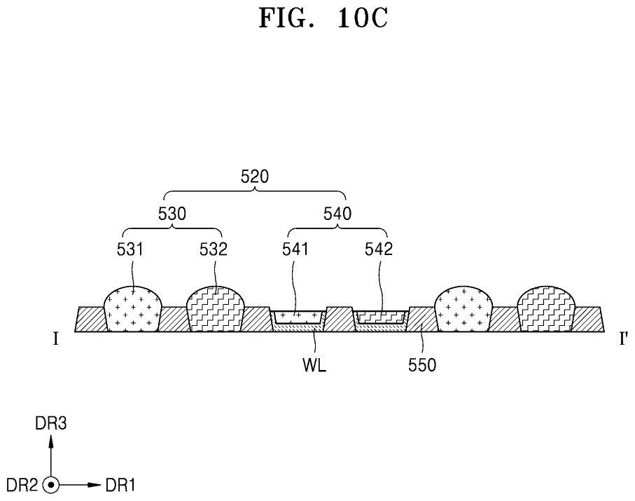

FIG. 9 is a cross-sectional view schematically illustrating another example of the I-I′ cross-section of FIG. 3, and FIGS. 10A to 10C are cross-sectional views illustrating an example of a process of manufacturing a display device of FIG. 9.

Referring to FIG. 9, color filters 520 may include convex color filters 530 each having a convex top surface and flat color filters 540 each having a flat top surface.

The convex color filters 530 and the flat color filters 540 may be alternately disposed in a repetitive pattern.

The proportion of the convex color filters 530 may be increased so as to improve lateral visibility and external light reflection, and the proportion of the flat color filters 540 may be increased so as to improve front light efficiency.

In other words, for the display device with improved lateral visibility and improved external light reflection, the convex color filters 530 and the flat color filters 540 may be alternately disposed and the total area of the convex color filters 530 may be designed to be greater than the total area of the flat color filters 540. For the display device with improved front light efficiency, the convex color filters 530 and the flat color filters 540 may be alternately disposed and the total area of the flat color filters 540 may be designed to be greater than the total area of the convex color filters 530.

A color filter layer may include a black matrix 550 surrounding the color filters 520. The black matrix 550 may be disposed on the same plane as the color filters 520.

The black matrix 550 may include openings in which the color filters 520 are disposed. In other words, one color filter 520 may be disposed in one opening.

The openings may include first openings in which the convex color filters 530 are disposed and second openings in which the flat color filters 540 are disposed.

Each of the color filters 520 may include a specific pigment according to the light-emitting element below the corresponding color filter 520. A first convex color filter 531 and a first flat color filter 541 may include the same pigment.

The top surface of the black matrix 550 may be hydrophobic, and the inner surface of the second opening OP2 may be hydrophilic. Due to this, even in a case in which the top surface of the convex color filter 530 is convex, ink may not overflow into the black matrix 550, and ink in the flat color filter 540 may also not overflow into the black matrix 550. In other words, the reliability of the display device may be improved.

For example, the display device may further include a hydrophilic layer WL on the lower portions of the flat color filters 540 and the inner surfaces of the second openings. Due to the hydrophilic layer WL, the ink in the flat color filter 540 may not overflow into the black matrix 550.

Referring to FIGS. 10A to 10C, a method of manufacturing a display device, according to the disclosure, may include forming a display layer including a substrate, a plurality of light-emitting elements, and a thin-film encapsulation layer, and forming a color filter layer on the display layer. The color filter layer may include color filters 520 formed by inkjet printing.

The forming of the display layer may include preparing the substrate, forming the plurality of light-emitting elements on the substrate, and forming the thin-film encapsulation layer on the light-emitting elements.

The forming of the color filter layer may include forming a black matrix 550 including openings, injecting ink, which is a material for the color filters 520, into the openings, and irradiating the injected ink with light.

In the forming of the black matrix 550, the openings in which the color filters 520 are to be disposed may be formed. For example, first openings in which convex color filters 530 are disposed and second openings in which flat color filters 540 are disposed may be formed.

The method may further include, between the forming of the black matrix 550 and the injecting of the ink, surface-treating the top surface of the black matrix 550 to be hydrophobic and surface-treating the inner surfaces of the second openings to be hydrophilic.

The surface-treating of the inner surfaces of the second openings to be hydrophilic may include forming a hydrophilic layer WL on the lower portions of the flat color filters 540 and the inner surfaces of the second openings.

After the surface-treating of the top surface of the black matrix 550 to be hydrophobic and the surface-treating of the inner surfaces of the second openings to be hydrophilic, ink may be injected into the openings.

After the ink is injected into the openings, the ink may be manufactured into the color filters 520 by irradiating the ink with light.

The color filters 520 manufactured by the method described herein may respectively overlap the light-emitting elements and include the convex color filters 530 each having a convex top surface and the flat color filters 540 each having a flat top surface. For example, the convex color filters 530 may be disposed in the first openings, and the flat color filters 540 may be disposed in the second openings.

The display device 10 according to an embodiment may be applied to various electronic devices. An electronic device according to an embodiment may include the display device 10 described herein, and may further include, in addition to the display device 10, a module or a device having additional functions.

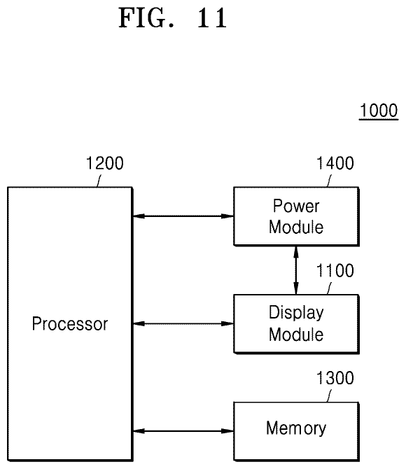

FIG. 11 is a block diagram of an electronic device 1000 according to an embodiment. Referring to FIG. 11, the electronic device 1000 according to an embodiment may include a display module 1100, a processor 1200, a memory 1300, and a power module 1400.

The processor 1200 may include at least one of a central processing unit (CPU), an application processor (AP), a graphics processing unit (GPU), a communication processor (CP), an image signal processor (ISP), or a controller.

Data information supportive of the operation of the processor 1200 or the display module 1100 may be stored in the memory 1300. In an example in which the processor 1200 executes an application stored in the memory 1300, an image data signal and/or an input control signal may be transmitted to the display module 1100, and the display module 1100 may process the received signal and output image information on a display screen.

The power module 1400 may include a power supply module, such as a power adapter or a battery device, and a power conversion module which converts power supplied by the power supply module and generate power for the operation of the electronic device 1000.

At least one of components of the electronic device 1000 may be included in the display device 10 according to the embodiments described herein. Furthermore, some of the individual modules functionally included in a single module may be included in the display device 10, and others of the individual modules may be provided separately from the display device 10. For example, the display device 10 may include the display module 1100, and the processor 1200, the memory 1300, and the power module 1400 may be provided in the form of other devices in the electronic device 1000 other than the display device 10.

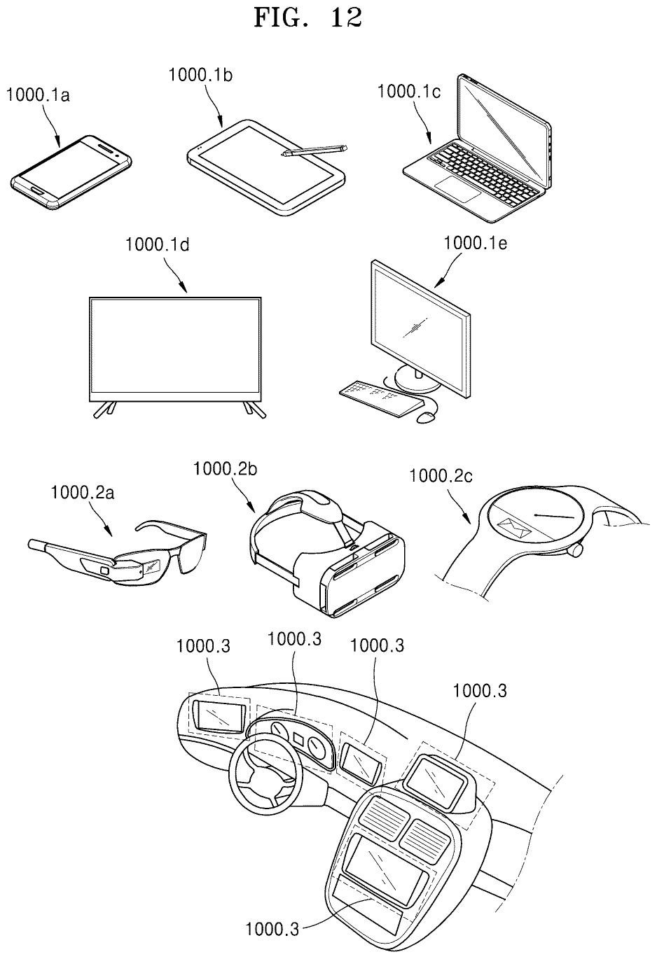

FIG. 12 is a schematic diagram of electronic devices according to various embodiments.

Referring to FIG. 12, various electronic devices to which the display device 10 according to embodiments are applied may include image display electronic devices, such as a smartphone 1000.1a, a tablet personal computer (PC) 1000.1b, a laptop 1000.1c, a television (TV) 1000.1d, or a desk monitor 1000.1e, wearable electronic devices including display modules, such as smart glasses 1000.2a, a head mounted display 1000.2b, or a smart watch 1000.2c, and vehicle electronic devices 1000.3 including display modules, such as a dashboard of an automobile, center information display (CID) on center fascia or dashboard, or a room mirror display.

According to embodiments, light efficiency, a viewing angle, and an external light reflection distribution may be controlled by disposing a convex color filter and a flat color filter.

However, the effects that may be obtained through the disclosure are not limited to those described herein, and other technical effects that are not mentioned herein will be clearly understood from the descriptions of the disclosure by those of ordinary skill in the art.

The embodiments described herein may be implemented independently, but it is obvious that the structure of each of the embodiments may be applied in combination to other embodiments.

The disclosure has been described with reference to the embodiments illustrated in the drawings, but this is an example. It will be understood by those of ordinary skill in the art that various modifications and equivalents may be made thereto. Accordingly, the true technical protection scope of the disclosure should be defined by the technical spirit of the appended claims.

Specific executions described in the embodiments are example embodiments, which do not limit the scope of the embodiments in any way. In addition, when there is no specific mention such as “essential,” “important,” or the like with reference to a component, it may not be a necessary component for the application of the disclosure.

The use of the term “the” and similar demonstratives in the specification of the embodiments (in particular, the claims) is to be construed to cover both the singular and the plural. In addition, when a range is described in the embodiments, it includes the invention to which individual values within the range are applied (unless otherwise indicated herein). This is the same as stating each individual value constituting the above range in the detailed description. Finally, operations constituting methods according to embodiments may be performed in any suitable order unless otherwise indicated herein or otherwise clearly contradicted by context. The embodiments are not necessarily limited by the order of description of operations. The use of any and all examples or exemplary terms provided in the embodiments is simply intended to describe the embodiments in detail, and the scope of the embodiments is not limited by the examples or exemplary terms unless otherwise claimed. In addition, it will be understood by those of ordinary skill in the art that various modifications, combinations and changes may be made according to design conditions and factors within the scope of the appended claims or equivalents thereof.

What is claimed is:

1. A display device comprising:
a substrate;
a plurality of light-emitting elements on the substrate;
a thin-film encapsulation layer on the plurality of light-emitting elements; and
a color filter layer on the thin-film encapsulation layer,
wherein:
the color filter layer comprises color filters respectively overlapping the plurality of light-emitting elements,
the color filters comprise convex color filters each having a convex top surface and flat color filters each having a flat top surface, and
some of the convex color filters and some of the flat color filters respectively overlap light-emitting elements which emit light of a same color.

2. The display device of claim 1, wherein:
the color filter layer further comprises a black matrix surrounding the color filters, and
the black matrix comprises first openings in which the convex color filters are disposed and second openings in which the flat color filters are disposed.

3. The display device of claim 1, wherein a first convex color filter of any one of the convex color filters and a first flat color filter of any one of the flat color filters respectively overlap the light-emitting elements which emit the light of the same color.

4. The display device of claim 3, wherein:
the first convex color filter and the first flat color filter comprise a same pigment, and
a concentration of the pigment as comprised in the first convex color filter is lower than a concentration of the pigment as comprised in the first flat color filter.

5. The display device of claim 3, further comprising a monomer layer below the first convex color filter.

6. The display device of claim 5, wherein:
the first convex color filter and the first flat color filter comprise a same pigment, and
a volume and a concentration of the pigment as comprised in the first convex color filter are equal to a volume and a concentration of the pigment as comprised in the first flat color filter.

7. The display device of claim 2, wherein a first thickness of the black matrix surrounding the convex color filters is less than a second thickness of the black matrix surrounding the flat color filters.

8. The display device of claim 2, wherein:
a top surface of the black matrix is hydrophobic, and
inner surfaces of the second openings are hydrophilic.

9. The display device of claim 8, further comprising a hydrophilic layer on lower portions of the flat color filters and on the inner surfaces of the second openings.

10. The display device of claim 1, wherein:
each of the plurality of light-emitting elements comprises a pixel electrode, a common electrode on the pixel electrode, and a light-emitting layer between the pixel electrode and the common electrode,
the display device further comprises a pixel defining layer covering edges of the pixel electrode and defining emission areas of the plurality of light-emitting elements, and
the color filters are disposed to respectively correspond to the emission areas.

11. A method of manufacturing a display device, the method comprising:
forming a display layer comprising a substrate, a plurality of light-emitting elements, and a thin-film encapsulation layer; and
forming a color filter layer on the display layer,
wherein:
the color filter layer comprises color filters formed by inkjet printing, and
the color filters respectively overlap the plurality of light-emitting elements and comprise convex color filters each having a convex top surface and flat color filters each having a flat top surface.

12. The method of claim 11, wherein:
the forming of the color filter layer comprises:
forming a black matrix comprising openings,
injecting ink, which is a material for the color filters, into the openings, and
irradiating the injected ink with light, and the openings comprise:
first openings in which the convex color filters are disposed; and
second openings in which the flat color filters are disposed.

13. The method of claim 12, wherein the injecting of the ink comprises injecting the ink into the second openings and then injecting the ink into the first openings.

14. The method of claim 12, further comprising, between the forming of the black matrix and the injecting of the ink, forming a monomer layer in the first openings.

15. The method of claim 12, further comprising, between the forming of the black matrix and the injecting of the ink, surface-treating a top surface of the black matrix such that the top surface is hydrophobic and surface-treating inner surfaces of the second openings such that the inner surfaces are hydrophilic.

16. The method of claim 15, wherein the surface-treating of the inner surfaces of the second openings such that the inner surfaces are hydrophilic comprises forming a hydrophilic layer on lower portions of the flat color filters and the inner surfaces of the second openings.

17. The method of claim 11, wherein a first convex color filter of any one of the convex color filters and a first flat color filter of any one of the flat color filters respectively overlap light-emitting elements which emit light of a same color.

18. The method of claim 12, wherein a depth of each of the first openings is less than a depth of each of the second openings.

19. An electronic device comprising a display device, the electronic device comprising:
a substrate;
a plurality of light-emitting elements on the substrate;
a thin-film encapsulation layer on the plurality of light-emitting elements; and
a color filter layer on the thin-film encapsulation layer,
wherein:
the color filter layer comprises color filters respectively overlapping the plurality of light-emitting elements, and
the color filters comprise convex color filters each having a convex top surface and flat color filters each having a flat top surface.

20. The electronic device of claim 19, wherein a first convex color filter of any one of the convex color filters and a first flat color filter of any one of the flat color filters respectively overlap light-emitting elements which emit light of a same color.
